(19) United States
(12) Patent Application Publication
(10) Pub. No.: US 2005/0201057 A1
(43) Pub. Date: Sep. 15, 2005

(54) Housing for electronic home entertainment devices

(76) Inventors: Markus Friebe, Nurnberg (DE); Johannes Spindler, Nuernberg (DE)

Correspondence Address: QUARLES & BRADY LLP, 411 E. WISCONSIN AVENUE, SUITE 2040, MILWAUKEE, WI, 53202-4497, US

(21) Appl. No.: 10/503,148

(22) PCT Filed: Jan. 31, 2003
(86) PCT No.: PCT/EP03/00957

§ 371 Date: May 19, 2005

(30) Foreign Application Priority Data
Feb. 2, 2002 (DE) 102 04 257.8

(51) Int. Cl. H05K 7/20

(52) U.S. Cl. 361/700

(57) ABSTRACT

The invention relates to a housing for a home entertainment device. Electrically conductive components (22) for the connection of the home electronics device are integrated into a transparent and/or opaque housing (20) for said home electronics device in such a way the said electrically conductive components cannot be perceived as such.

The present invention concerns a housing for an electronic home entertainment device.

Housings have become known for electronic home entertainment devices which are made, for example, from transparent material. Furthermore, housings have become known for electronic home entertainment devices which have several housing parts, for example, a first housing part which contains the actual electronic home entertainment device and a second housing part which can be used, for example, as support, in order to bring the first housing part into the position required for operation.

However, the known housings for electronic home entertainment devices have the disadvantage that the connection, for example, of the electric supply lines, antennas, loudspeakers, etc., is involved. In addition, as a result of the lines used for the connection, the entire appearance of the electronic home entertainment device can be disturbed. Multi-part housings or housing with a lower part, in which the connections are to be made in the upper part of the housing, represent another problem, since in this case connecting lines lying around represent a significant accident risk.

Therefore, it is the task of the present invention to provide a housing from an electronic home entertainment device in which the necessary connection lines can be connected to the housing or to the electronic home entertainment device without any problems.

In the present invention, this task is solved by the characteristics of claim 1.

It is assumed that a transparent and/or opaque housing for an electronic home entertainment device has electrically-conducting components for the connection of the electronic home entertainment device, where the electrically-conducting components cannot be perceived as such.

The advantage of the invention can be seen in the fact that the components needed for the connection of the electronic home entertainment device are contained in the housing so that the electronic home entertainment device can be connected simply. In addition, the components needed for connection are not perceived as distracting, since they are not visible, or they are integrated into the housing in such a way that they cannot be perceived. By avoiding connecting lines lying around, any accident risks are also eliminated.

Other advantages of the present invention follow from the dependent claim as well as from the description of embodiments of the housings according to the invention for electronic home entertainment devices given below, with the aid of figures.

The following are shown:

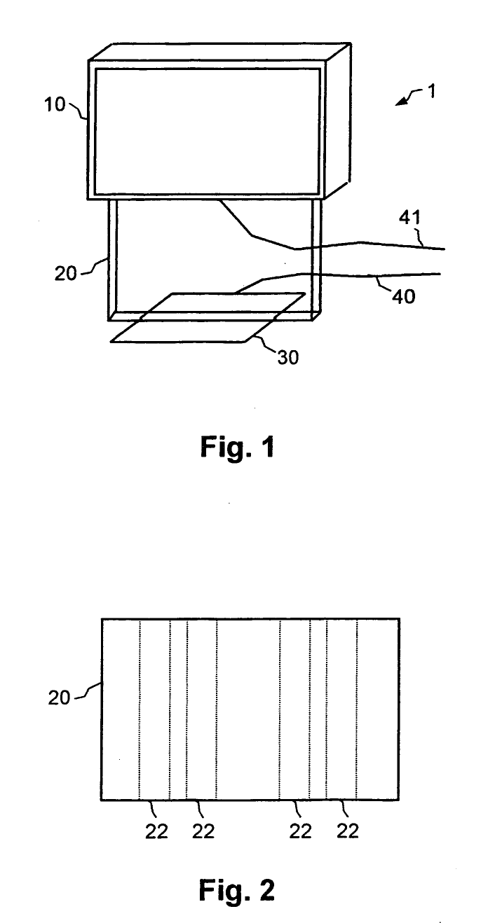

FIG. 1 is a housing for an electronic home entertainment device,

FIG. 2 is a first embodiment of a part of the housing according to FIG. 1,

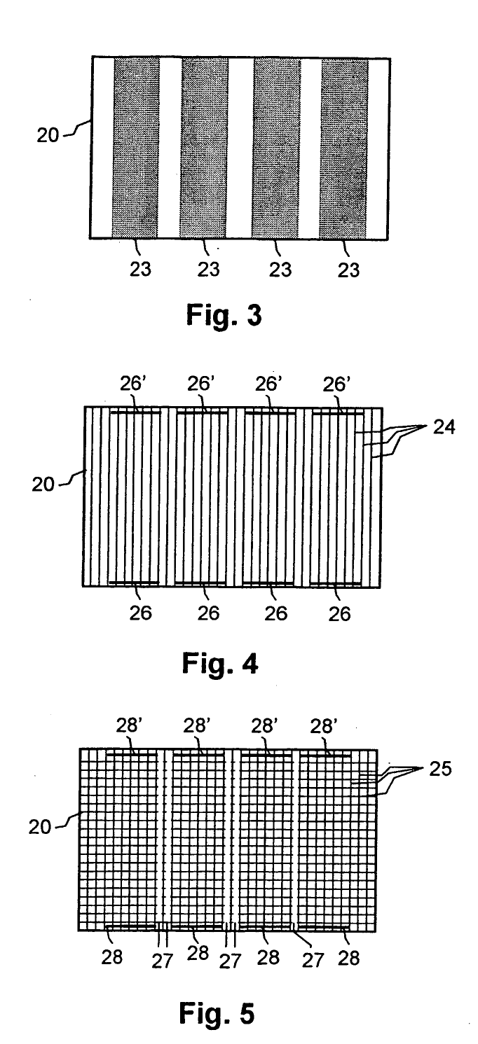

FIG. 3 is a second embodiment according to the invention of a part of the housing according to FIG. 1,

FIG. 4 is a third embodiment according to the invention of a part of the housing according to FIG. 1, and

FIG. 5 is a fourth embodiment according to the invention of a part of the housing according to FIG. 1.

In order to facilitate understanding of the present invention, only those components are shown in the figures which are of importance in connection with the invention. Equivalent components in the different figures have the same reference numbers.

FIG. 1 shows a housing 10, 20, 30 for an electronic home entertainment device 1. In the example shown, the electronic home entertainment device 1 is a television equipment which consists of a first housing part 10, with the actual components of the television equipment, such as screen, electronics, etc., a second housing part 20, for example, a support, as well as a foot 30. Other housing solutions and housing solutions for other electronic home entertainment devices are possible. The housing 10, 20, 30 or parts thereof, but especially the second housing part 20, is made of a transparent and/or opaque material, and especially glass, milk glass, smoky glass, acrylic glass, etc., are suitable for this.

The connecting line designated with reference 41 shows the situation known from the state of the art, in which the connecting line 41 is connected to the first housing part 10—with the known disadvantages described at the outset, for example, increased danger of accident.

The connecting line designated with reference 40 represents the state according to the invention, in which the connecting line 40 is connected, for example, to the foot 30. It is also possible to connect the connecting line directly to the second housing part 20, and this is done advantageously in the floor area, that is, at the height of foot 30. Instead of the single connecting line 40 shown in the example, other connecting lines can be connected, for example, for electrical supply, antenna, loudspeaker, etc., to foot 30 and/or to the second housing part 20.

FIG. 2 shows a first embodiment according to the invention of the second housing part 20 according to FIG. 1. The second housing part 20 has electrically-conducting components 22, which in turn are connected to the connecting line(s) 40, for example, through the foot 30 or directly, and on the other hand to the electronic home entertainment device 1 in the first housing part 10.

The electrically-conducting components 22 are transparent and thus not perceivable. Especially suitable for the electrically-conducting components 22 is indium-tin oxide, which is applied, for example, in conducting-path-like structures. Advantageously, the electrically-conducting components 22 are applied on a surface of the second housing part 20, which lies inside the second housing part 20, and, for this purpose, for example, two glass panes can be connected to one another. This would avoid danger of coming into contact with the electrically-conducting components 22 when these are at a higher electric potential, for example in the case of a power supply.

In order to satisfy the requirements of the connection to be made, the electrically-conducting components 22 can be adjusted with regard to the width of the conducting-path-like structures and their distances to one another. For example, wide electrical components 22 at a greater distance from one another are used for the electrical supply in order to be able to conduct higher currents and, on the other hand, to avoid sparking.

FIG. 3 shows a second embodiment according to the invention of the second housing part 20 according to FIG. 1. The second housing part 20 has electrically-conducting components 23 which, on the one hand, are connected with connecting line(s) 40, for example, through foot 30 or directly, and, on the other hand, to the electronic home entertainment device 1 in the first housing part 10.

The electrically-conducting components 23 are partially transparent and form a component of the design of at least the second housing part 20. Therefore, the electrical components 23 are not perceived since they are adapted to the appearance of the housing. Especially suitable for electrically-conducting components 23 are metals, for example, silver, gold, copper, aluminum, which can be applied onto the conducting-path-like structures in very thin layers. Advantageously, the electrically-conducting components 23 are applied, for example, by evaporation, onto a surface of the second housing part 20, which lies inside the second housing part 20 for which purpose, for example, two glass panes can be connected to one another. As a result of this, the danger that can arise upon contact with electrically-conducting components 23 is eliminated, when these are at a higher electrical potential, for example, in the case of a power supply.

In order to satisfy the requirement for the particular connection to be made, the electrically-conducting components 23 are adapted with regard to the width of the conducting-path-like structures and their distances to one another. For example, for the electrical supply, wide electrical components 23 with a greater distance from one another are used, on the one hand to be able to conduct larger currents, and, on the other hand, to avoid sparking. However, in order to maintain uniform appearance it is preferable to have the electrically-conducting components 23 designed as conducting paths with the same width and the same distance. In this case, for safe electrical insulation, as a rule, distances between the conducting paths which can no longer be resolved by the human eye are sufficient, as a result of which a homogeneous appearance is produced.

If the electrical requirements make it necessary, several conducting paths 23 can be combined to a line. In this case, the corresponding conducting paths are connected to one another on the upper and lower end in an electrically-conducting manner, for example, in the region of the first housing part 10 and of foot 30, so that the connections are not visible. Similarly, it is possible, if the distance between the conducting paths 23 is not sufficient for insulation, to not use one or several of the conducting paths 23 for connection purposes.

FIG. 4 shows a third embodiment according to the invention of the second housing part 20 according to FIG. 1. The second housing part 20 has electrically-conducting components 24 which are connected on the one hand to the connecting line(s) 40 via contacts 26, for example, through the foot 30 or directly and, on the other hand, through contacts 26′ to the electronic home entertainment device 1 in the first housing part 10.

The electrically-conducting components 24 are visible and form a component of the design at least of the second housing part 20. Thus, the electrically-conducting components 24 are not perceived since they are part of the appearance of the housing. Especially suitable for the electrically-conducting components 24 are metals, for example, silver, gold, copper, aluminum, which are applied in conducting-path-like structures. Advantageously, the electrically-conducting components 24 are applied on a surface of the second housing 20, for example, by etching the metallized surface or by pressing-on or adhering electrically-conducting paths which lie inside the second housing part 20, for example, for which purpose two glass panes can be connected to one another. As a result of this, the dangers that could arise upon contact with the electrically-conducting components 24 when these are at a higher electrical potential are avoided, for example, in the case of the power supply. Similarly, the electrically-conducting components 24 can be produced by introducing electrical conductors, for example, metallic threads into the material of housing 20. Preferably, it is provided that the electrically-conducting components 24 are designed to be narrow.

In order to satisfy the requirements for the connections to be made, the electrically-conducting components 24 are connected to one another in an electrically-conducting manner via the already-mentioned contacts 26, 26′ at the upper and lower end. This can be done, for example, in the region of the first housing part 10 and of the foot 30, so that the connections are not visible. In order to be able to insulate the electrically-conducting components 24 from one another, sufficient distances are chosen between the electrically-conducting components 24 or one or several of the electrically-conducting components 24 are not used for connection purposes.

FIG. 5 shows a fourth embodiment according to the invention of the second housing part 20 according to FIG. 1. The second housing part 20 has electrically-conducting components 25, which, on the one hand, are connected to the connecting line(s) 40 through contacts 28, for example, through foot 30 or directly, and, on the other hand, through contacts 28′, to the electronic home entertainment device 1 in the first housing part 10.

The embodiment according to FIG. 5 represents a variant of the embodiment according to FIG. 4, where the electrically-conducting components 25 according to FIG. 5 are designed as a grid structure in order to increase the electrical conductivity. Otherwise, the realization of the embodiment according to FIG. 5 follows the embodiment according to FIG. 4.

In order to satisfy the requirements of the particular connection to be made, the corresponding grid surfaces are connected to one another with contacts 28, 28′ in an electrically-conducting manner at the upper and lower end. This can be done, for example, in the region of the first housing part 10 and of foot 30, so that the connections are not visible. In order to be able to ensure the insulation of the electrical components 25 from one another, sufficient distances between the electrical components 25 can be provided with one or several interruptions 27 of the grid structure.

In case a multi-part separable housing is used, for example, consisting of first housing part 10 and second housing part 20, where the housing parts 10 and 20 are connected separably, it can be arranged that between housing parts 10 and 20 corresponding connections are provided, for example, plug contacts, separable connecting lines, etc. With the aid of these connections, the electrically-conducting components 22, 23, 24, 25 of the second housing part 20 can be connected to the electronic home entertainment device 1 in the first housing part 10.

In the examples described, the electrically-conducting components 22 to 25 run parallel to two of the outside edges of housing 20, however, it is obvious that the electrically-conducting components 22 to 25 could also run at an angle with respect to the outside edges of housing 20 and/or may not have a straight course. However, preferably the electrically-conducting components 22 to 25 run parallel to one another.

1. Housing (10, 20, 30) for an electronic home entertainment device (1), which is comprised of transparent and/or opaque material and electrically-conducting components (22, 23, 24, 25) for connection (40) of the electronic home entertainment device (1), whereby the electrically-conducting components (22; 23; 24; 25) cannot be perceived as such, wherein the electrically-conducting components are at least partially transparent, wherein the housing (10, 20, 30) is designed as a multi-part separable housing (10, 20, 30) and wherein the electrical connections are provided as plug contacts or separable connecting lines for producing separable electrical connections between the electrically-conducting components (22; 23; 24; 25) and the home entertainment device (1).

2. Housing according to claim 1, wherein selected ones of the electrically-conducting components (22) are fully transparent.

3. Housing according to claim 2, wherein the selected ones of the electrically-conducting components (22) are made of indium-tin oxide.

4. Housing according to claim 1, wherein selected ones of the electrically-conducting components (23) are partially transparent.

5. Housing according to claim 4, wherein the electrically-conducting components (23) consist of a thin metal layer.

6. Housing according to claim 5, wherein the thin metal layer (23) is made of gold and/or silver and/or copper and/or aluminum.

7. Housing according to claim 1, wherein the electrically-conducting components (24; 25) are design elements of at least parts of the housing (10; 20; 30).

8. Housing according to claim 7, wherein the electrically-conducting components (24; 25) are designed as conducting paths or threads.

9. Housing according to claim 8, wherein the conducting paths or threads (24; 25) are made of metal, especially of gold and/or silver and/or copper and/or aluminum.

10. Housing according to claim 7, wherein the electrically-conducting components (25) are arranged as a grid.

11. Housing according to claim 1, wherein the electrically-conducting components (22; 23; 24; 25) lie inside the housing (10; 20; 30) and that the housing (10, 20, 30) is designed as an insulator, at least in the region of the electrically-conducting components (22; 23; 24; 25).

12. Housing according to claim 1, wherein electrically-conducting components (22; 23; 24; 25) run parallel to one another.

13. Housing according to claim 1, wherein the electrically-conducting components (22; 23; 24; 25) run parallel to the outside edges of the housing (10, 20, 30).

14. Housing according to claim 1, wherein the electrically-conducting components (22; 23; 24; 25) run at an angle to the outside edges of the housing (10, 20, 30).

15. Housing according to, wherein the electrically-conducting components (22; 23; 24; 25) can be connected together with contacts (26; 28).

16. Housing according to claim 15 wherein the contacts (26; 28) run in the region of the housing (10, 30) in which they are not visible.

17. Housing according to claim 1, wherein the housing (10, 20, 30) is designed as a multi-part separable housing (10, 20, 30) and that electrical connections are provided, especially plug contacts or separable bonding lines to produce separable electrical connections between the electrically-conducting components (22; 23; 24; 25) and the electronic home entertainment device (1).
